(19) United States
(12) Patent Application Publication
(10) Pub. No.: US 2004/0245601 A1
(43) Pub. Date: Dec. 9, 2004

(54) Semiconductor device

(75) Inventor: Hidetoshi Koike, Yokohama-shi (JP)

Correspondence Address: FOLEY AND LARDNER, SUITE 500, 3000 K STREET NW, WASHINGTON, DC, 20007, US

(73) Assignee: KABUSHIKI KAISHA TOSHIBA

(21) Appl. No.: 10/835,595

(22) Filed: Apr. 30, 2004

(30) Foreign Application Priority Data
May 7, 2003 (JP) 2003-129428

(51) Int. Cl. H01L 29/00

(52) U.S. Cl. 257/529

(57) ABSTRACT

A semiconductor device is disclosed, which comprises a metal fuse formed in a fuse region defined above an element isolation region of a semiconductor substrate; and an interconnection provided under the metal fuse along the metal fuse in plane pattern, and made of a material hard to be blowout by a laser beam irradiated for blowing the metal fuse.

### CROSS-REFERENCE TO RELATED APPLICATIONS

This application is based upon and claims the benefit of priority from the prior Japanese Patent Application No. 2003-129428, filed May 7, 2003, the entire contents of which are incorporated herein by reference.

### BACKGROUND OF THE INVENTION

1. Field of the Invention

The present invention relates to a semiconductor device. In particular, the present invention relates to structural arrangement of a fuse interconnection layer and another interconnection layer. For example, the structural arrangement is employed in a memory LSI, memory embedded LSI, etc.

2. Description of the Related Art

With the advance of high density and large capacity of semiconductor memories, it is difficult to provide a chip having no defects. For this reason, it is common sense in memory LSIs, memory embedded LSIs to employ the redundancy configuration including a redundancy circuit. In order to replace a failed cell in the LSI with a spare cell, the following technique is employed in general. According to the technique, the address of the failed cell is detected and stored, and thereafter, a fuse made of metal such as Cu or Al is blown using laser. When the address of the failed cell is designated, a spare cell is selected in place. Recently, in order to avoid the reduction of yield due to the large capacity of LSIs, the number of the fuses has been extremely increased; for this reason, the fuse region area is increasing.

FIG. 19 is a plan view showing a pattern of a conventional semiconductor device, in particular, a layout pattern of a metal fuse and underlying interconnection, which are formed in an LSI device having a four-layer Cu metal interconnection structure.

In FIG. 19, 11 denotes a metal fuse, 12 denotes a fuse control circuit interconnection, 13 denotes a connecting portion of the metal fuse 11 and the fuse control circuit interconnection 12. A reference numeral 14 denotes a fuse blow window for passing a fuse blow laser beam irradiated from the outside. A reference numeral 15 denotes an LSI interconnection.

FIG. 20 to FIG. 25 are cross-sectional views taken along the line XVIII-XVIII in the pattern of the semiconductor device shown in FIG. 19, for explaining a method of manufacturing the semiconductor device.

As shown in FIG. 20, an element separation region 19 is formed in a silicon substrate 18. In addition, source/drain regions, not shown, of a MOS transistor is formed in an element formation region and a polysilicon gate interconnection, not shown, is formed above the element formation region.

Then, as shown in FIG. 21, a boron-phosphorus silicate glass (BPSG) film, for example, is deposited as a first interlayer insulation film 21, and the first interlayer insulation film 21 is flattened by chemical mechanical polishing (CMP) technique. After that, a first contact hole, not shown, is formed in the first interlayer insulation film 21 by lithography technique, and tungsten is embedded in the first contact hole.

In addition, a Cu interconnection is formed by, for example, single damascene technique. Specifically, an silicon oxide (SiO₂) film 23, for example, is deposited as a second interlayer insulation film 23 over the substrate 18, and a first interconnection groove is formed in the second interlayer insulation film 23 by lithography technique. Thereafter, a first Cu film 24 is deposited over the substrate 18, and the first Cu film 24 is flattened by chemical mechanical polishing technique. Then, a silicon nitride (SiN) film, for example, is deposited over the substrate 18 as a thin barrier film 25, to prevent Cu from being oxidized and diffused.

Subsequently, as shown in FIG. 22, a Cu interconnection is formed by dual damascene technique, for example. Specifically, an silicon oxide (SiO₂) film 26, for example, is deposited over the substrate 18 as a third interlayer insulation film 26, and a second contact hole 27 is formed in the third interlayer insulation film 26 and the thin barrier film 25 by lithography technique. Thereafter, a second Cu film 28 is deposited over the substrate 18, and the second Cu film 28 is flattened by chemical mechanical polishing technique. Then, a silicon nitride (SiN) film 29, for example, is deposited over the substrate 18 as a thin barrier film 29, to prevent Cu from being oxidized and diffused.

Thereafter, as shown in FIG. 23, an silicon oxide (SiO₂) film 30, for example, is deposited over the substrate 18 as a fourth interlayer insulation film 30, and a third contact hole 31 is formed in the fourth interlayer insulation film 30 and the thin barrier film 29 by lithography technique. Thereafter, a third Cu film 32 is deposited over the substrate 18, and the third Cu film 32 is flattened by chemical mechanical polishing technique. Then, a silicon nitride (SiN) film, for example, is deposited over the substrate 18 as a thin barrier film 33, to prevent Cu from being oxidized and diffused.

After that, as shown in FIG. 24, an silicon oxide (SiO₂) film 34, for example, is deposited over the substrate 18 as a fifth interlayer insulation film 34, and a fourth contact hole 35 is formed in the fifth interlayer insulation film 34 and the thin barrier film 33 by lithography technique. Thereafter, a fourth Cu film 36 is deposited over the substrate 18, and the fourth Cu film 36 is flattened by chemical mechanical polishing technique. Then, a silicon nitride (SiN) film 37, for example, is deposited over the substrate 18 as a thin barrier film 37, to prevent Cu from being oxidized and diffused. In the four-layer Cu metal interconnection structure, the uppermost interconnection, i.e., the fourth Cu film 36, constitutes a metal fuse.

After that, as shown in FIG. 25, a phosphorus silicate glass (PSG) film 38, for example, is deposited over the substrate 18 as a passivation film 38, and part of the passivation film 38, which is on the fuse region, is etched out, so that a fuse blow opening window 39 is formed in the passivation film 38. The fuse blow opening window 39 correspond to the fuse blow opening window 14 in FIG. 19.

The first Cu film 24 in FIG. 25 corresponds to the LSI interconnection 15 shown in FIG. 19. The first Cu film 24 is formed under the metal fuse 36 and outside the fuse region, that is, outside the fuse blow opening window 39.

In the conventional art shown in FIG. 19, the LSI interconnection 15 is made of the same interconnection material as metal fuse 11. The LSI interconnection 15 is positioned apart from a fuse blow window 14 to avoid the fuse region. This positioning is to avoid the following disadvantage. That is, if the LSI interconnection 15 is formed in the lower layer from the metal fuse 11 in the fuse region and between fuses in plane pattern, and when the metal fuse 11 is blown out, damage is given to the LSI interconnection 15 made of the same material as the metal fuse 11. As seen from the foregoing, the fuse region is a hindrance to LSI pattern design.

JPN. PAT. APPLN. KOKAI Publication No. 11-224900 discloses the following technique. According to the technique, a fuse link is formed of a material having a melting point lower than the material of another multilayer interconnection, and thereby, only the fuse link is selectively blown. By doing so, it is possible to form interconnections below the fuse link.

JPN. PAT. APPLN. KOKAI Publication No. 2002-368094 discloses the following technique. According to the technique, a fuse interconnection is arranged on an interlayer insulating film. The interlayer insulating film is formed with an interconnection layer having a width smaller than the fuse interconnection under the fuse interconnection. By doing so, the area of the interconnection region can be reduced.

The conventional semiconductor device has the following problem. In order to avoid giving damage to the LSI interconnection layer made of the same material as the metal fuse in blowing the metal fuse by laser beam irradiation, the LSI interconnection layer is arranged to avoid the fuse region. For this reason, the fuse region is a hindrance to LSI pattern design.

### BRIEF SUMMARY OF THE INVENTION

According to an aspect of the present invention, there is provided a semiconductor device comprising:

a metal fuse formed in a fuse region defined above an element isolation region of a semiconductor substrate; and

an interconnection provided under the metal fuse along the metal fuse in plane pattern, and made of a material hard to be blowout by a laser beam irradiated for blowing the metal fuse.

According to another aspect of the present invention, there is provided a semiconductor device comprising:

a metal fuse formed in a fuse region defined above an element isolation region of a semiconductor substrate; and

an interconnection provided under the metal fuse in a direction crossing the metal fuse in plane pattern, and made of a material hard to be blowout by a laser beam irradiated for blowing the metal fuse.

According to a further aspect of the present invention, there is provided a semiconductor device comprising:

a metal fuse formed in a fuse region defined above an element region of a semiconductor substrate; and

an interconnection formed of an impurity diffusion layer formed in the element region in a direction along the metal fuse in plane pattern.

According to a further aspect of the present invention, there is provided a semiconductor device comprising:

a metal fuse formed in a fuse region defined above an element region of a semiconductor substrate; and

an interconnection formed of an impurity diffusion layer formed in the element region in a direction crossing the metal fuse in plane pattern. According to a further aspect of the present invention, there is provided a semiconductor device comprising:

a metal interconnection formed in a trimming interconnection region defined above an element isolation region of a semiconductor substrate; and

an interconnection provided under the metal interconnection, and made of a material hard to be blowout by a laser beam irradiated for blowing the metal interconnection.

### BRIEF DESCRIPTION OF THE SEVERAL VIEWS OF THE DRAWING

FIG. 1 is a plan view showing a pattern of a semiconductor device according to a first embodiment of the present invention;

FIG. 2 is a cross-sectional view taken along the line II-II in the pattern of the semiconductor device shown in FIG. 1, for explaining a method of manufacturing the semiconductor device,

FIG. 3 is a cross-sectional view taken along the line II-II in the pattern of the semiconductor device shown in FIG. 1, and taken at a manufacturing step following the step of FIG. 2;

FIG. 4 is a cross-sectional view taken along the line II-II in the pattern of the semiconductor device shown in FIG. 1, and taken at a manufacturing step following the step of FIG. 3;

FIG. 5 is a cross-sectional view taken along the line II-II in the pattern of the semiconductor device shown in FIG. 1, and taken at a manufacturing step following the step of FIG. 4;

FIG. 6 is a cross-sectional view taken along the line II-II in the pattern of the semiconductor device shown in FIG. 1, and taken at a manufacturing step following the step of FIG. 5;

FIG. 7 is a cross-sectional view taken along the line II-II in the pattern of the semiconductor device shown in FIG. 1, and taken at a manufacturing step following the step of FIG. 6;

FIG. 8 is a plan view showing a pattern of a semiconductor device according to a second embodiment of the present invention;

FIG. 9 is a cross-sectional view taken along the line IX-IX in the pattern of the semiconductor device shown in FIG. 8, for explaining a method of manufacturing the semiconductor device;

FIG. 10 is a cross-sectional view taken along the line IX-IX in the pattern of the semiconductor device shown in FIG. 9, and taken at a manufacturing step following the step of FIG. 9;

FIG. 11 is a cross-sectional view taken along the line IX-IX in the pattern of the semiconductor device shown in FIG. 9, and taken at a manufacturing step following the step of FIG. 10;

FIG. 12 is a cross-sectional view taken along the line IX-IX in the pattern of the semiconductor device shown in FIG. 9, and taken at a manufacturing step following the step of FIG. 11;

FIG. 13 is a cross-sectional view taken along the line IX-IX in the pattern of the semiconductor device shown in FIG. 9, and taken at a manufacturing step following the step of FIG. 12;

FIG. 14 is a cross-sectional view taken along the line IX-IX in the pattern of the semiconductor device shown in FIG. 9, and taken at a manufacturing step following the step of FIG. 13;

FIG. 15 is a plan view showing a first modification example of the pattern of the semiconductor device shown in FIG. 1 according to the first embodiment of the present invention;

FIG. 16 is a plan view showing a second modification example of the pattern of the semiconductor device shown in FIG. 1 according to the first embodiment of the present invention;

FIG. 17 is a cross-sectional view taken along the line XVII-XVII in the pattern of the modification example shown in FIG. 16;

FIG. 18 is a plan view showing a modification example of the second modification example shown in FIG. 16;

FIG. 19 is a plan view showing a pattern of a conventional semiconductor device; and

FIG. 20 is a cross-sectional view taken along the line XX-XX in the pattern of the conventional semiconductor device shown in FIG. 19, for explaining a method of manufacturing the semiconductor device.

FIG. 21 is a cross-sectional view taken along the line XX-XX in the pattern of the conventional semiconductor device shown in FIG. 20, and taken at a manufacturing step following the step of FIG. 20;

FIG. 22 is a cross-sectional view taken along the line XX-XX in the pattern of the conventional semiconductor device shown in FIG. 20, and taken at a manufacturing step following the step of FIG. 21;

FIG. 23 is a cross-sectional view taken along the line XX-XX in the pattern of the conventional semiconductor device shown in FIG. 20, and taken at a manufacturing step following the step of FIG. 22;

FIG. 24 is a cross-sectional view taken along the line XX-XX in the pattern of the conventional semiconductor device shown in FIG. 20, and taken at a manufacturing step following the step of FIG. 23;

FIG. 25 is a cross-sectional view taken along the line XX-XX in the pattern of the conventional semiconductor device shown in FIG. 20, and taken at a manufacturing step following the step of FIG. 24.

### DETAILED DESCRIPTION OF THE INVENTION

Embodiments of the present invention will be explained below with reference to the accompanying drawings.

<First embodiment>

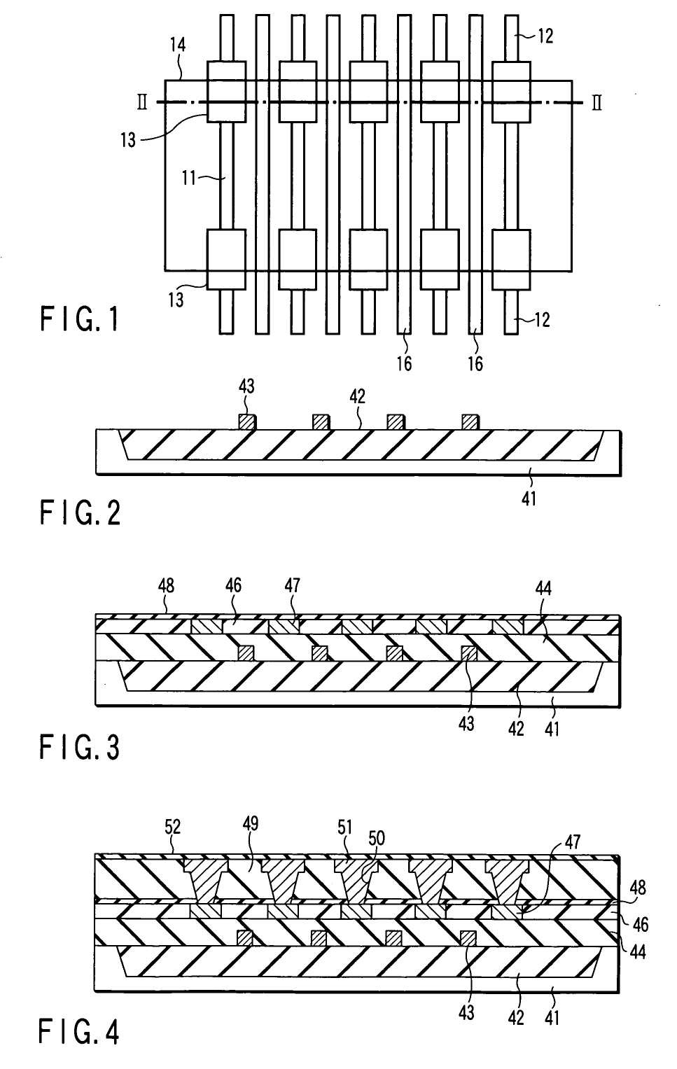

FIG. 1 is a plan view showing a pattern of a semiconductor device according to a first embodiment of the present invention, in particular, a layout pattern of a metal fuse and underlying interconnection, which are formed in an LSI device having a four-layer Cu metal interconnection structure.

In FIG. 1, 11 denotes a metal fuse, 12 denotes a fuse control circuit interconnection, 13 denotes a connecting portion of the metal fuse 11 and the fuse control circuit interconnection 12. A reference numeral 14 denotes a fuse blow window for passing a fuse blow laser beam irradiated from the outside. A reference numeral 16 denotes an LSI interconnection, for example, a polysilicon interconnection connected to the gate electrode of a MOS transistor.

FIG. 2 to FIG. 7 are cross-sectional views taken along the line II-II in the pattern of the semiconductor device shown in FIG. 1, for explaining a method of manufacturing the semiconductor device.

As shown in FIG. 2, an element separation region 42 is formed in a silicon substrate 41. In addition, source/drain regions, not shown, of a MOS transistor is formed in an element formation region and a polysilicon gate interconnection 43 is formed on the element separation region 42.

Then, as shown in FIG. 3, a boron-phosphorus silicate glass (BPSG) film 44, for example, is deposited over the substrate 41 as a first interlayer insulation film 44, and the first interlayer insulation film 44 is flattened by chemical mechanical polishing (CMP) technique. After that, a first contact hole, not shown, is formed in part of the first interlayer insulation film 44, which is in the element region, by lithography technique, and tungsten is embedded in the first contact hole.

In addition, a Cu interconnection is formed by, for example, single damascene technique. Specifically, an silicon oxide (SiO₂) film 46, for example, is deposited as a second interlayer insulation film 46 over the substrate 41, and a first interconnection groove is formed in the second interlayer insulation film 46 by lithography technique. Thereafter, a first Cu film 47 is deposited over the substrate 41, and the first Cu film 47 is flattened by chemical mechanical polishing technique. Then, a silicon nitride (SiN) film 48, for example, is deposited over the substrate 41 as a thin barrier film 48, to prevent Cu from being oxidized and diffused.

Subsequently, as shown in FIG. 4, a Cu interconnection is formed by dual damascene technique, for example. Specifically, an silicon oxide (SiO₂) film 49, for example, is deposited over the substrate 41 as a third interlayer insulation film 49. A second contact hole 50 is formed in the third interlayer insulation film 49 and the thin barrier film 48 by lithography technique, followed by forming a second interconnection groove in the third interlayer insulation film 49 by lithography technique. Thereafter, a second Cu film 51 is deposited over the substrate 41, and the second Cu film 51 is flattened by chemical mechanical polishing technique. Then, a silicon nitride (SiN) film 52, for example, is deposited over the substrate 41 as a thin barrier film 52, to prevent Cu from being oxidized and diffused.

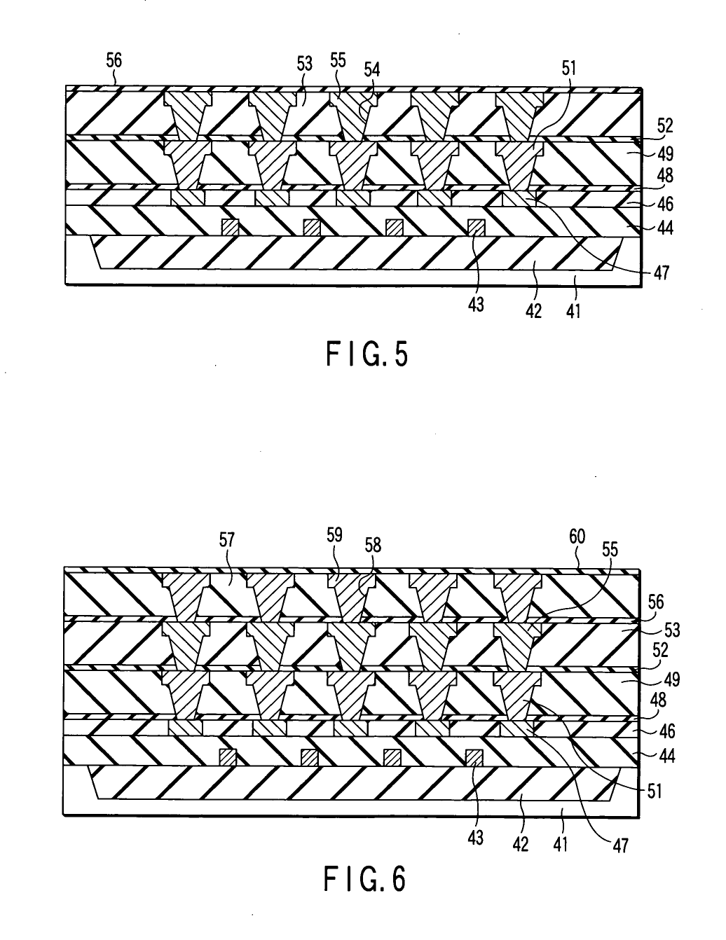

Thereafter, as shown in FIG. 5, an silicon oxide (SiO₂) film 53, for example, is deposited over the substrate 41 as a fourth interlayer insulation film 53. A third contact hole 54 is formed in the fourth interlayer insulation film 53 and the thin barrier film 29 by lithography technique, followed by forming a third interconnection groove in the fourth interlayer insulation film 53 by lithography technique. Thereafter, a third Cu film 55 is deposited over the substrate 41, and the third Cu film 55 is flattened by chemical mechanical polishing technique. Then, a silicon nitride (SiN) film 56, for example, is deposited over the substrate 41 as a thin barrier film 56, to prevent Cu from being oxidized and diffused.

After that, as shown in FIG. 6, an silicon oxide (SiO₂) film 57, for example, is deposited over the substrate 41 as a fifth interlayer insulation film 57. A fourth contact hole 58 is formed in the fifth interlayer insulation film 57 and the thin barrier film 56 by lithography technique, followed by forming a fourth interconnection groove in the fifth interlayer insulation film 57 by lithography technique. Thereafter, a fourth Cu film 59 is deposited over the substrate 41, and the fourth Cu film 59 is flattened by chemical mechanical polishing technique. Then, a silicon nitride (SiN) film 60, for example, is deposited over the substrate 41 as a thin barrier film 60, to prevent Cu from being oxidized and diffused. In the four-layer Cu metal interconnection structure, the uppermost interconnection, i.e., the fourth Cu film 59, constitutes a metal fuse.

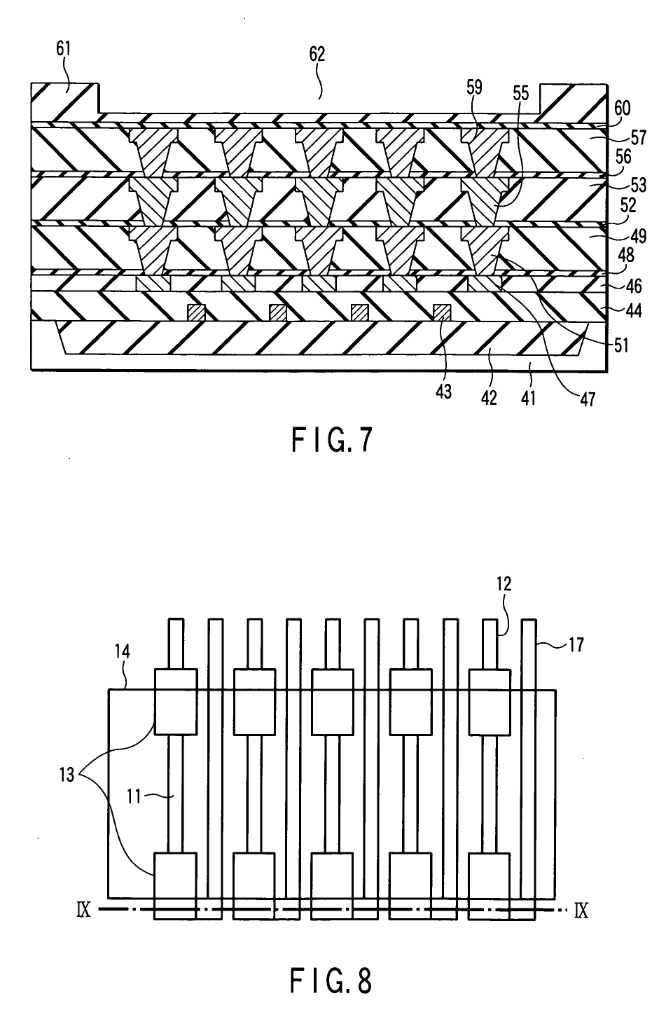

After that, as shown in FIG. 7, a phosphorus silicate glass (PSG) film 61, for example, is deposited over the substrate 41 as a passivation film 61, and part of the passivation film 61, which is on the fuse region, is etched out, so that a fuse blow opening window 62 is formed in the passivation film 61. The fuse blow opening window 62 correspond to the fuse blow opening window 14 in FIG. 1.

The polysilicon gate interconnection 43 shown in FIG. 7 corresponds to the LSI interconnection 16 shown in FIG. 1. Similarly, the metal fuse 59 shown in FIG. 7 corresponds to the metal fuse 11 shown in FIG. 1.

According to the present first embodiment, as shown in FIG. 7, the polysilicon gate interconnection 43 is provided under the metal fuse 59 in the fuse region. Also, as shown in the plan pattern of FIG. 1, the LSI interconnection 16 corresponding to the polysilicon gate interconnection 43 extends along the metal fuse 11 and between the metal fuses 11.

A laser beam suitable for blowing the fuse 11 made of a metal (e.g., Cu) is irradiated to the fuse 11. In this case, the LSI interconnection 16 is made of silicon material, and silicon material is hard to be blown out by the laser beam. Thus, no damage is given to the LSI interconnection 16. The reason is as follows. The typical wavelength of the laser beam used for blowing the metal fuse 11 is 1321 nm, and the absorption coefficient α of metal (Cu, Al) to the laser beam is about 1×10⁶ cm⁻¹. On the contrary, the absorption coefficient α of polysilicon is about 2×10^{2 cm}⁻¹. Thus, there is a four-digit difference between the two absorption coefficients, i.e., between metal and polysilicon.

Since the LSI interconnection 16 made of silicon material is hard to be blown out by the laser beam, it is possible that the LSI interconnection 16 is provided under the metal fuse 11 and between metal fuses 11 in the plane pattern. This serves to reduce the occupied region of the LSI interconnection 16. In addition, the fuse region is no hindrance to LSI pattern design, so that the degree of freedom in the LSI pattern design can be improved.

In the current generation of the 90 μm minimum design rule, the width of the metal fuse 59 is about 1 μm, the pitch of the metal fuses 59 is 2 μm, and the width of the interconnection 43 is 0.1 μm. However, in the next generation in which the micronization is further advanced, the widths of the fuse and interconnection are decreased accordingly. In other words, with the advanced generation, the pitch of the metal fuses 59 is less than 2 μm, and the width of the interconnection 43 is less than 0.1 μm. The width of the metal fuse 59 is in general not defined in accordance with the minimum design rule, and thus even in the advanced generation, the width of the metal fuse 59 may be about 1 μm. Nonetheless, it can be less than about 1 μm.

It is effective to provide the interconnection 43 i.e. the metal fuse 43 as described in the embodiment particularly when the pitch of the metal fuses 59 is less than 2 μm. To be specific, the diameter of the laser beam used for the fuse-blow cannot be reduced to be smaller than 2 μm by the existing technology. Thus, when the pitch of the metal fuses 59 is less than 2 μm and the laser beam of the 2 μm diameter is applied to the semiconductor device, the laser beam is applied to the interconnection 43 to blown out the interconnection 43 if the interconnection 43 is formed of material easy to be blown out by the laser beam. However, since in the embodiment the interconnection 43 is formed of material hard to be blown out by the laser beam, no damage is given to the interconnection 43, even when the pitch of the metal fuses 59 is less than 2 μm and the laser beam of the 2 μm diameter is applied to the semiconductor device.

<Second embodiment>

FIG. 8 is a plan view showing a pattern of a semiconductor device according to a second embodiment of the present invention, in particular, a layout pattern of a metal fuse and underlying interconnection, which are formed in an LSI device having a four-layer Cu metal interconnection structure.

In FIG. 8, 11 denotes a metal fuse, 12 denotes a fuse control circuit interconnection, 13 denotes a connecting portion of the metal fuse 11 and the fuse control circuit interconnection 12. A reference numeral 14 denotes a fuse blow window for passing a fuse blow laser beam irradiated from the outside. A reference numeral 17 denotes an LSI interconnection, for example, a polysilicon interconnection.

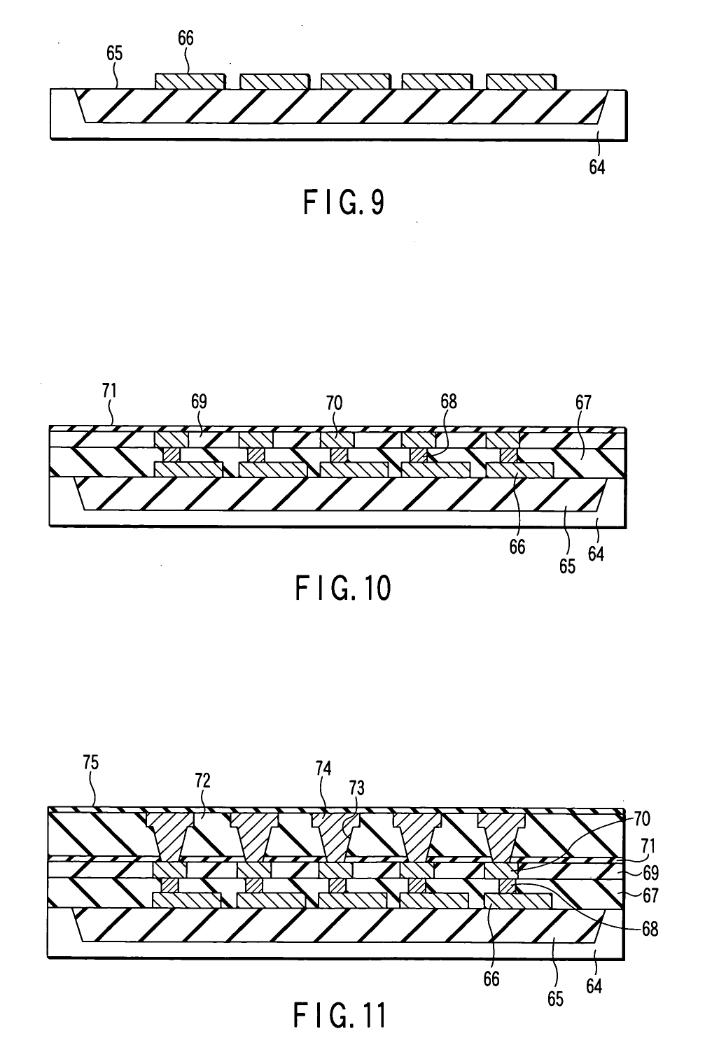

FIG. 9 to FIG. 14 are cross-sectional views taken along the line IX-IX in the pattern of the semiconductor device shown in FIG. 8, for explaining a method of manufacturing the semiconductor device.

As shown in FIG. 9, an element separation region 65 is formed in a silicon substrate 64. In addition, source/drain regions, not shown, of a MOS transistor is formed in an element formation region and a polysilicon gate interconnection 66 is formed on the element separation region 65.

Then, as shown in FIG. 10, a boron-phosphorus silicate glass (BPSG) film 67, for example, is deposited over the substrate 64 as a first interlayer insulation film 67, and the first interlayer insulation film 67 is flattened by chemical mechanical polishing (CMP) technique. After that, a first contact hole, not shown, is formed in part of the first interlayer insulation film 67, which is in the element region, by lithography technique, and tungsten is embedded in the first contact hole.

In addition, a Cu interconnection is formed by, for example, single damascene technique. Specifically, an silicon oxide (SiO₂) film 69, for example, is deposited as a second interlayer insulation film 69 over the substrate 64, and a first interconnection groove is formed in the second interlayer insulation film 69 by lithography technique. Thereafter, a first Cu film 70 is deposited over the substrate 64, and the first Cu film 70 is flattened by chemical mechanical polishing technique. Then, a silicon nitride (SiN) film 71, for example, is deposited over the substrate 64 as a thin barrier film 71, to prevent Cu from being oxidized and diffused.

Subsequently, as shown in FIG. 11, a Cu interconnection is formed by dual damascene technique, for example. Specifically, an silicon oxide (SiO₂) film 72, for example, is deposited over the substrate 64 as a third interlayer insulation film 72. A second contact hole 73 is formed in the third interlayer insulation film 72 and the thin barrier film 71 by lithography technique, followed by forming a second interconnection groove in the third interlayer insulation film 72 by lithography technique. Thereafter, a second Cu film 74 is deposited over the substrate 64, and the second Cu film 74 is flattened by chemical mechanical polishing technique. Then, a silicon nitride (SiN) film 75, for example, is deposited over the substrate 64 as a thin barrier film 75, to prevent Cu from being oxidized and diffused.

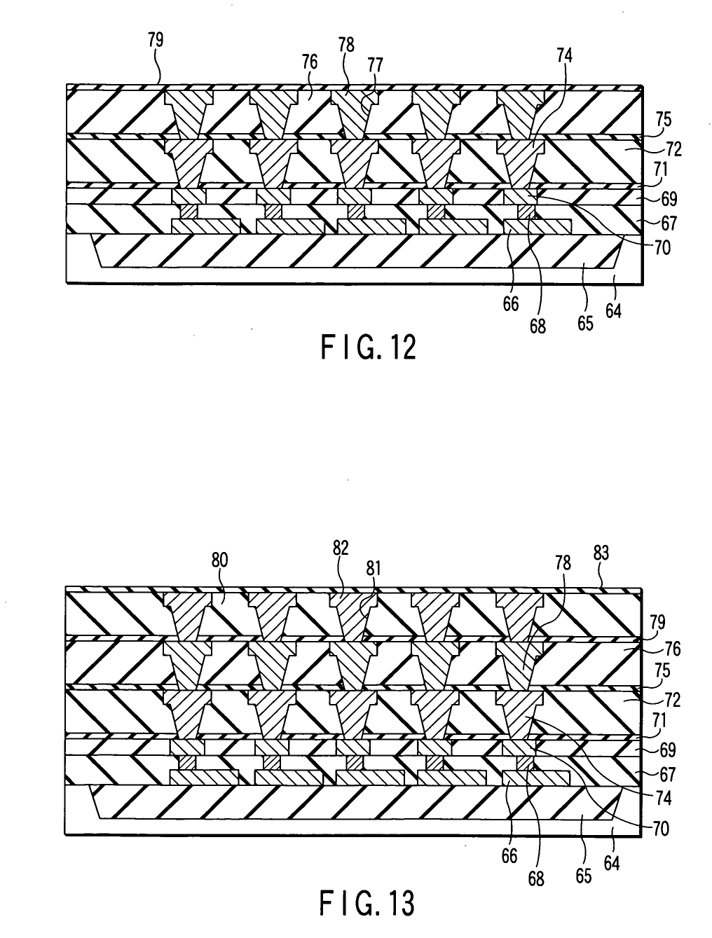

Thereafter, as shown in FIG. 12, an silicon oxide (SiO₂) film 76, for example, is deposited over the substrate 64 as a fourth interlayer insulation film 76. A third contact hole 77 is formed in the fourth interlayer insulation film 76 and the thin barrier film 75 by lithography technique, followed by forming a third interconnection groove in the fourth interlayer insulation film 76 by lithography technique. Thereafter, a third Cu film 78 is deposited over the substrate 64, and the third Cu film 78 is flattened by chemical mechanical polishing technique. Then, a silicon nitride (SiN) film 79, for example, is deposited over the substrate 64 as a thin barrier film 79, to prevent Cu from being oxidized and diffused.

After that, as shown in FIG. 13, an silicon oxide (SiO₂) film 80, for example, is deposited over the substrate 64 as a fifth interlayer insulation film 80. A fourth contact hole 81 is formed in the fifth interlayer insulation film 80 and the thin barrier film 79 by lithography technique, followed by forming a fourth interconnection groove in the fifth interlayer insulation film 80 by lithography technique. Thereafter, a fourth Cu film 82 is deposited over the substrate 64, and the fourth Cu film 82 is flattened by chemical mechanical polishing technique. Then, a silicon nitride (SiN) film 83, for example, is deposited over the substrate 64 as a thin barrier film 83, to prevent Cu from being oxidized and diffused. In the four-layer Cu metal interconnection structure, the uppermost interconnection, i.e., the fourth Cu film 82, constitutes a metal fuse.

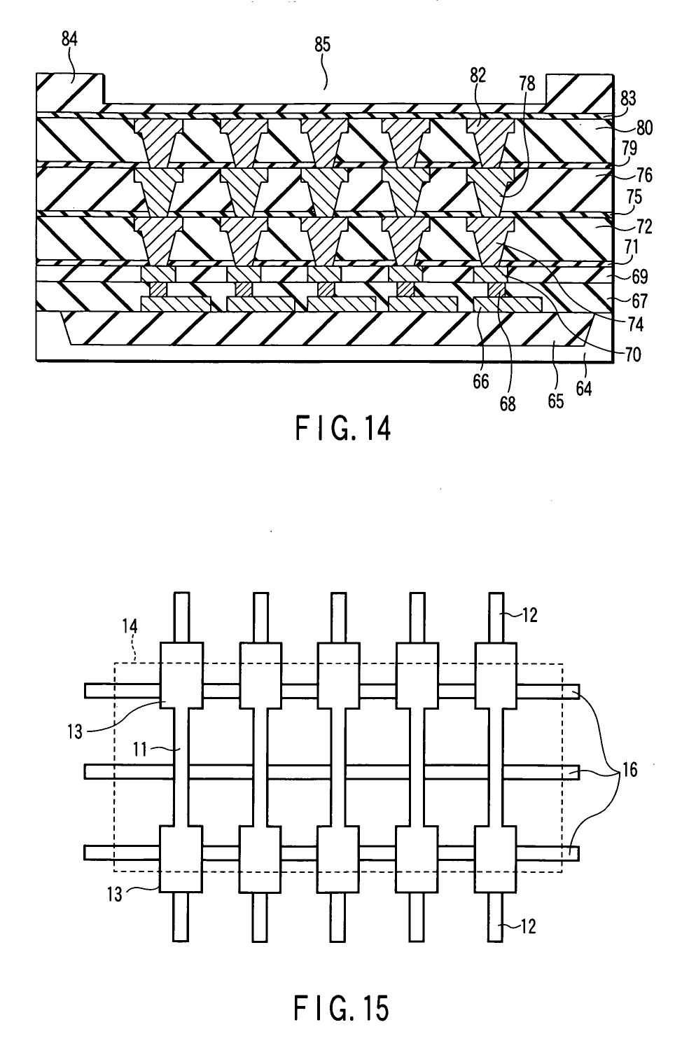

After that, as shown in FIG. 14, a phosphorus silicate glass (PSG) film 84, for example, is deposited over the substrate 64 as a passivation film 84, and part of the passivation film 84, which is on the fuse region, is etched out, so that a fuse blow opening window 85 is formed in the passivation film 84. The fuse blow opening window 85 correspond to the fuse blow opening window 14 in FIG. 8.

The polysilicon gate interconnection 66 shown in FIG. 14 corresponds to the fuse control circuit interconnection 17 shown in FIG. 8. Similarly, the metal fuse 82 formed by the uppermost Cu film 82 shown in FIG. 14 corresponds to the metal fuse 11 shown in FIG. 8. According to the present second embodiment, as shown in FIG. 14, the polysilicon gate interconnection 66 is provided under the metal fuse 82 in the fuse region. Also, as shown in the plan pattern of FIG. 8, the fuse control circuit interconnection 17 connected to one end of the metal fuse 11 is turned back from the connection and extends along the metal fuse 11.

A laser beam suitable for blowing the fuse 11 made of a metal (e.g., Cu) is irradiated to the fuse 11. In this case, the polysilicon gate interconnection 66, i.e., the fuse control circuit interconnection 17 is made of silicon material, and silicon material is hard to be blown out by the laser beam. Thus, no damage is given to the fuse control circuit interconnection 17. The reason is as follows. The typical wavelength of the laser beam used for blowing the metal fuse 11 is 1321 nm, and the absorption coefficient α of metal (Cu, Al) to the laser beam is about 1×10⁶ cm⁻¹. On the contrary, the absorption coefficient α of polysilicon is about 2×10² cm⁻¹. Thus, there is a four-digit (four decimal-place) difference between the two absorption coefficients, i.e., between metal and polysilicon.

Since the fuse control circuit interconnection 17 made of silicon material is hard to be blown out by the laser beam, it is possible that the fuse control circuit interconnection 17 is provided under the metal fuse 11 and between metal fuses 11 in the plane pattern. This serves to reduce the occupied region of the fuse control circuit interconnection 17. In addition, the fuse region is no hindrance to fuse control circuit pattern design, so that the degree of freedom in the fuse control circuit pattern design can be improved.

<First Modification Example>

FIG. 15 is a plan view showing a modification example of the pattern of the semiconductor device shown in FIG. 1 according to the first embodiment of the present invention.

In the modification example, the LSI interconnection 16 is arranged in a direction crossing the metal fuse 11 in plane pattern. The other parts or portions are the same as those in the first embodiment, and description thereof is omitted.

Also in the pattern of this modification example, substantially the same advantages as in the first embodiment are provided.

<Second Modification Example>

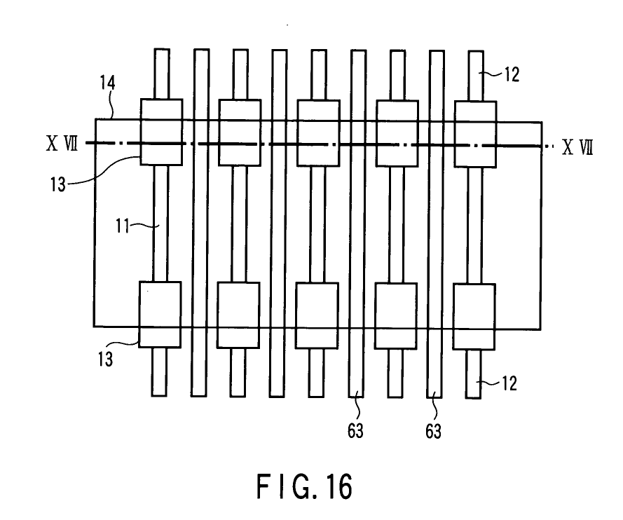

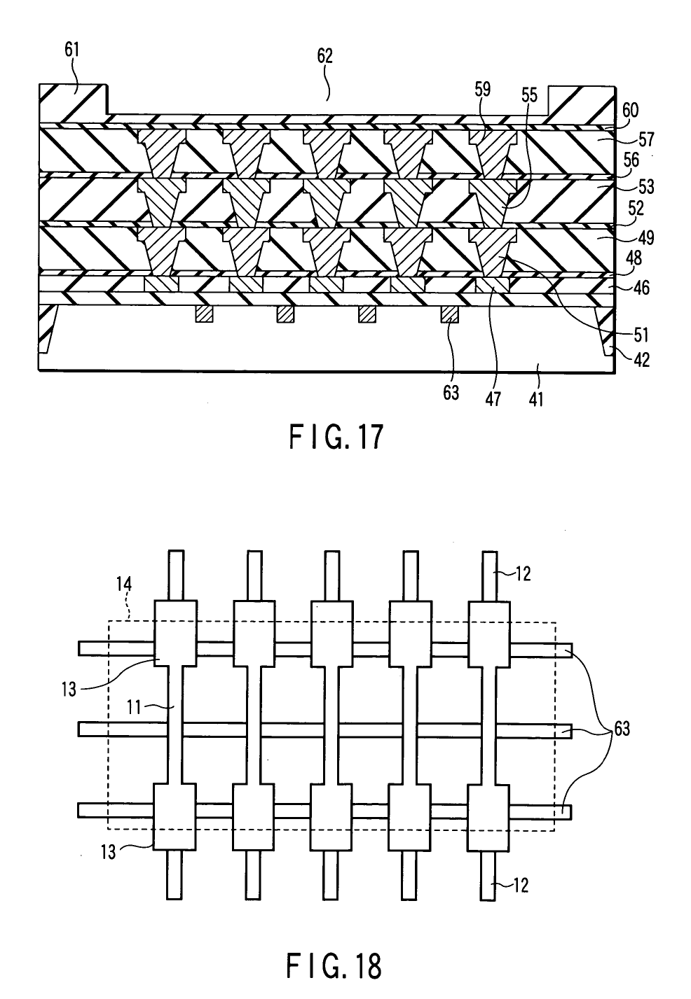

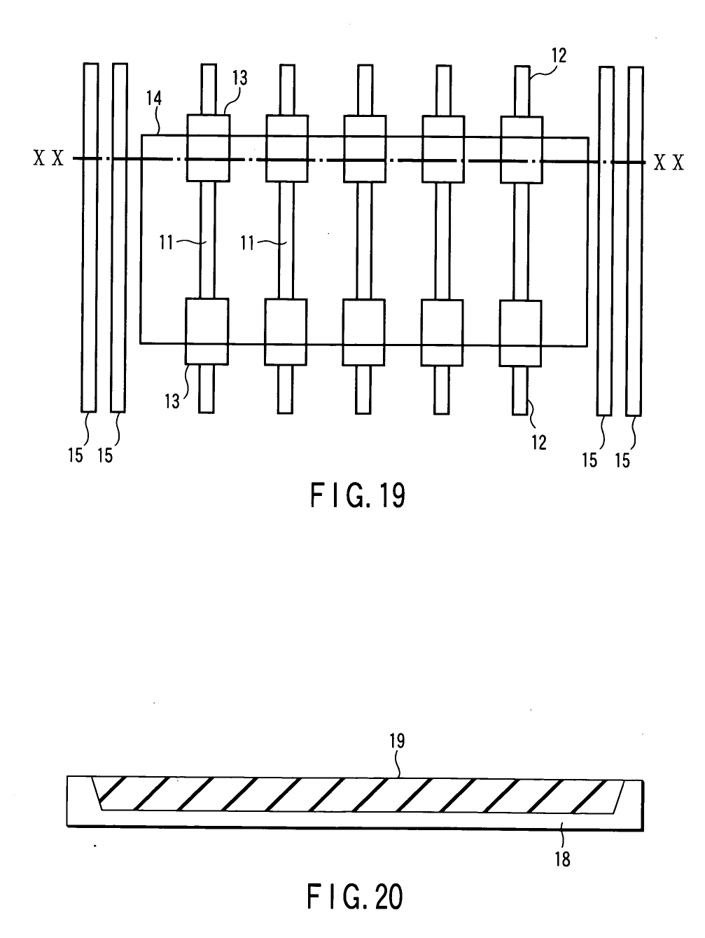

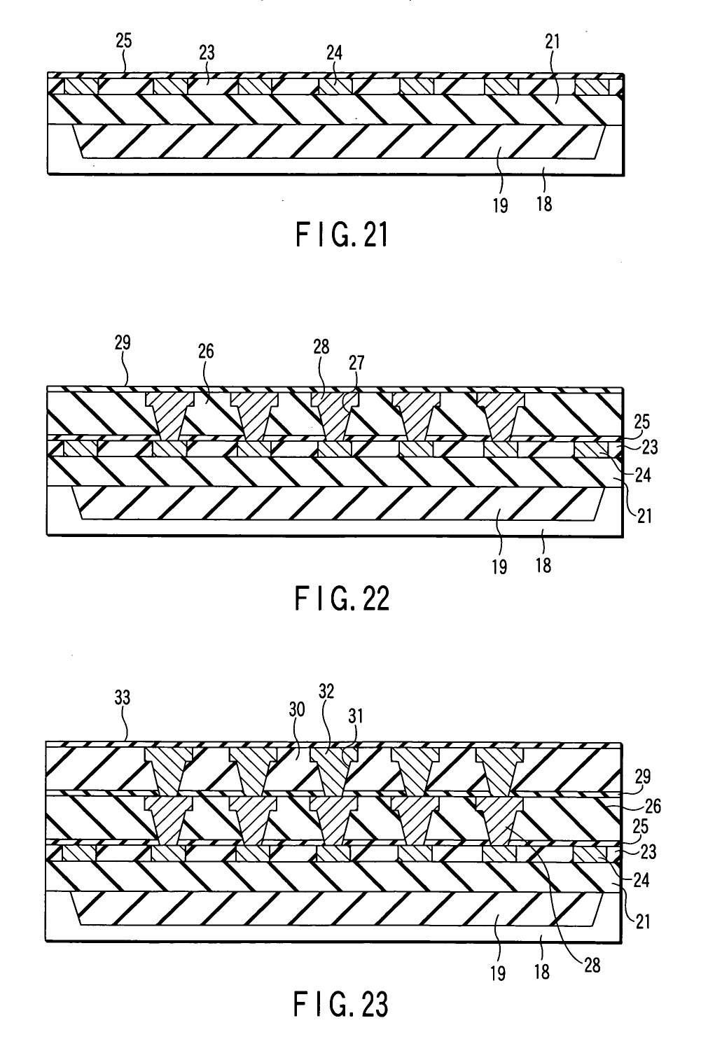

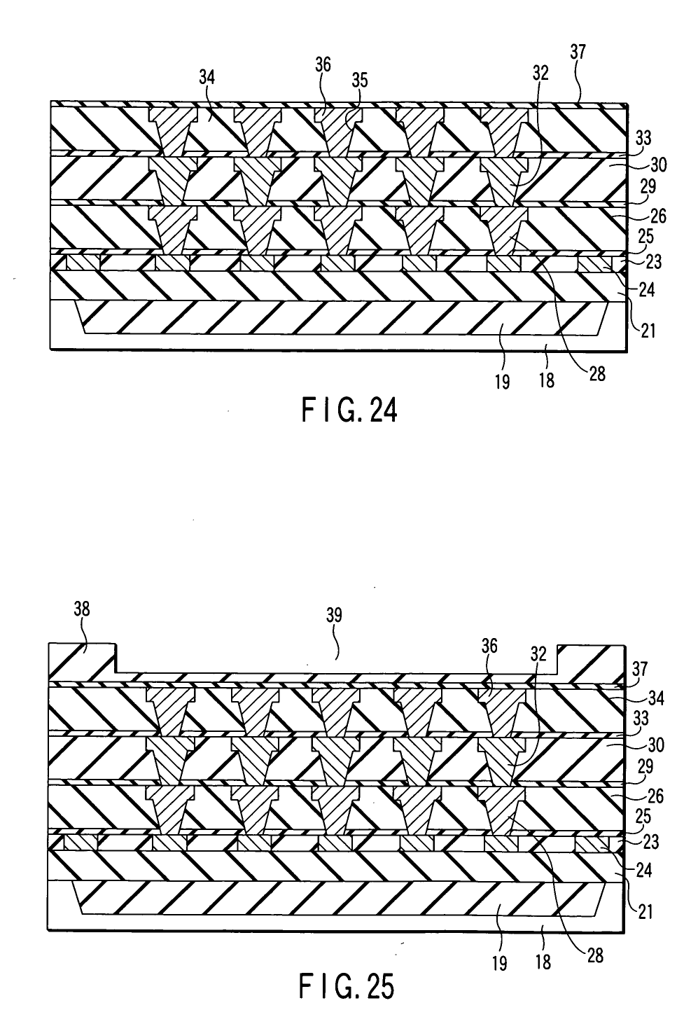

FIG. 16 is a plan view showing a second modification example of the pattern of the semiconductor device shown in FIG. 1 according to the first embodiment of the present invention. FIG. 17 is a cross-sectional view taken along the line XVII-XVII in the pattern of the modification example shown in FIG. 16.

As shown in FIG. 16, the pattern in the plan view of this modification is similar to the pattern shown in FIG. 1 of the first embodiment. However, the structure shown in FIG. 17 differs from that shown in FIG. 1 in that the fuse region is defined above the element formation region of the silicon substrate, as shown in FIG. 17. In addition, the LSI interconnection is formed of an impurity diffusion layer 63 formed in the substrate. The impurity diffusion layer 63 is provided under the metal fuse 11, and extends along the metal fuse 11 and between the metal fuses 11.

Also in the pattern of this modification example, substantially the same advantages as in the first embodiment are provided. A polysilicon interconnection may be used in place of the impurity diffusion layer 63.

FIG. 18 is a plan view showing a modification example of the pattern of the semiconductor device of the second modification example shown in FIG. 16.

In this modification example, the LSI interconnection, i.e., the impurity diffusion layer 63, is arranged in a direction crossing the metal fuse 11 in plane pattern. The other parts or portions are the same as those in the second modification example, and description thereof is omitted.

In the current generation of the 90 μm minimum design rule, the width of the metal fuse 59 is about 1 μm, the pitch of the metal fuses 59 is 2 μm, and the width of the interconnection 63 is 0.11 μm. However, in the next generation in which the micronization is further advanced, the widths of the fuse and interconnection are decreased accordingly. In other words, with the advanced generation, the pitch of the metal fuses 59 is less than 2 μm, and the width of the interconnection 63 is less than 0.11 μm. The width of the metal fuse 59 is not in general defined in accordance with the minimum design rule, and even in the advanced generation, the width of the metal fuse 59 may be about 1 μm. Nonetheless, it can be less than about 1 μm the width of the metal fuse 59 does not necessarily need to decrease. Of course, the width of the metal fuse 59 may be reduced to a thickness less than 1 μm.

When the pitch of the metal fuses 59 is less than 2 μm, it is relatively preferable to provide the interconnection 63 i.e. the metal fuse 63 as described in the embodiment. To be specific, the diameter of the laser beam used for the fuse-blow cannot be reduced to be smaller than 2 μm by the existing technology. Thus, when the pitch of the metal fuses 59 is less than 2 μm and the laser beam of the 2 μm diameter is applied to the semiconductor device, the laser beam is applied to the interconnection 63 to blow out it if the interconnection 43 is formed of material easy to be blown out by the laser beam. However, since in the embodiment the interconnection 63 is formed of material hard to be blown out by the laser beam, no damage is given to the interconnection 63, even when the pitch of the metal fuses 59 is less than 2 μm.

Also in the pattern of this modification example, substantially the same advantages as in the first embodiment are provided. A polysilicon interconnection may be used in place of the impurity diffusion layer 63.

<Third Modification Example>

In the first embodiment, the polysilicon interconnection is formed as the LSI interconnection. A metal silicide film of polysilicon interconnection covered with a thin metal layer may be used, instead of the polysilicon interconnection. For example, the metal silicide film is TaSi, CoSi, TiSi, NiSi, etc. In this case, the absorption coefficient α of the metal silicide film to the laser beam is less than 1/3 of the metal fuse (i.e., the metal silicide film has the absorption coefficient α of three times or more as much as the metal fuse). Therefore, substantially the same advantages as described in the first embodiment are obtained.

Embodiments and modification example of the present invention are not limited to the case of blowing the metal fuse storing the address of the failed cell by laser beam in memory LSIs and memory embedded LSIs. The present invention is also applicable to the case of blowing a metal interconnection (equivalent to metal fuse), which is a trimming control object, using laser beam in general LSIs.

According to the foregoing embodiments and modification example of the present invention, the semiconductor device has the following advantages. When blowing a metal interconnection such as a metal fuse using laser beam irradiation, no damage is given to the underlying LSI interconnection layer. The metal interconnection region such as fuse region does not hinder to LSI interconnection arrangement and LSI pattern design, so that the degree of freedom can be improved in design.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a metal fuse formed in a fuse region defined above an element isolation region of a semiconductor substrate; andk
an interconnection provided under the metal fuse along the metal fuse in plane pattern, and made of a material hard to be blowout by a laser beam irradiated for blowing the metal fuse.

2. The semiconductor device according to claim 1, wherein the metal fuse is formed of an uppermost metal layer of a multilayer metal interconnection structure, and a plurality of the metal fuses are arranged in parallel in a plan pattern.

3. The semiconductor device according to claim 1, wherein the interconnection extends between adjacent those of the metal fuses along the metal fuses.

4. The semiconductor device according to claim 1, wherein the interconnection is made of polysilicon.

5. The semiconductor device according to claim 2, wherein the interconnection is made of polysilicon.

6. The semiconductor device according to claim 3, wherein the interconnection is made of polysilicon.

7. The semiconductor device according to claim 1, wherein the interconnection is made of metal silicide.

8. The semiconductor device according to claim 2, wherein the interconnection is made of metal silicide.

9. The semiconductor device according to claim 3, wherein the interconnection is made of metal silicide.

10. The semiconductor device according to claim 1, wherein the interconnection is connected to one end of the metal fuse.

11. The semiconductor device according to claim 1, wherein a width of the metal fuse is about 1 μm, a pitch of the metal fuses is equal to or less than 2 μm, and a width of the interconnection is equal to or less than 0.1 μm.

12. A semiconductor device comprising:
a metal fuse formed in a fuse region defined above an element isolation region of a semiconductor substrate; and
an interconnection provided under the metal fuse in a direction crossing the metal fuse in plane pattern, and made of a material hard to be blowout by a laser beam irradiated for blowing the metal fuse.

13. The semiconductor device according to claim 12, wherein the metal fuse is formed of an uppermost metal layer of a multilayer metal interconnection structure, and a plurality of the metal fuses are arranged in parallel in a plan pattern.

14. The semiconductor device according to claim 12, wherein the interconnection is made of polysilicon.

15. The semiconductor device according to claim 12, wherein the interconnection is made of metal silicide.

16. The semiconductor device according to claim 12, wherein a width of the metal fuse is about 1 μm, a pitch of the metal fuses is equal to or less than 2 μm, and a width of the interconnection is equal to or less than 0.1 μm.

17. A semiconductor device comprising:
a metal fuse formed in a fuse region defined above an element region of a semiconductor substrate; and
an interconnection formed of an impurity diffusion layer formed in the element region in a direction along the metal fuse in plane pattern.

18. The semiconductor device according to claim 17, wherein the metal fuse is formed of an uppermost metal layer of a multilayer metal interconnection structure, and a plurality of the metal fuses are arranged in parallel in a plan pattern.

19. The semiconductor device according to claim 17, wherein a width of the metal fuse is about 1 μm, a pitch of the metal fuses is equal to or less than 2 μm, and a width of the interconnection is equal to or less than 0.11 μm.

20. A semiconductor device comprising:
a metal fuse formed in a fuse region defined above an element region of a semiconductor substrate; and
an interconnection formed of an impurity diffusion layer formed in the element region in a direction crossing the metal fuse in plane pattern.

21. The semiconductor device according to claim 20, wherein the metal fuse is formed of an uppermost metal layer of a multilayer metal interconnection structure, and a plurality of the metal fuses are arranged in parallel in a plan pattern.

22. The semiconductor device according to claim 20, wherein a width of the metal fuse is about 1 μm, a pitch of the metal fuses is equal to or less than 2 μm, and a width of the interconnection is equal to or less than 0.11 μm.

23. A semiconductor device comprising:
a metal interconnection formed in a trimming interconnection region defined above an element isolation region of a semiconductor substrate; and
an interconnection provided under the metal interconnection, and made of a material hard to be blowout by a laser beam irradiated for blowing the metal interconnection.

24. The semiconductor device according to claim 23, wherein the metal interconnection is formed of an uppermost metal interconnection of a multilayer metal interconnection structure, and a plurality of the metal interconnections are arranged in parallel in a plan pattern.

25. The semiconductor device according to claim 23, wherein a width of the metal fuse is about 1 μm, a pitch of the metal fuses is equal to or less an 2 μm, and a width of the interconnection is equal or less than 0.1 μm.
